(19) United States
(12) Patent Application Publication
(10) Pub. No.: US 2026/0198318 A1
(43) Pub. Date: Jul. 9, 2026

(54) SEMICONDUCTOR PACKAGE AND METHODS OF FORMING AND USING THE SAME

(71) Applicant: Taiwan Semiconductor Manufacturing Company Limited, Hsinchu (TW)

(72) Inventors: Sheng-Ta LIN, Gongguan Township (TW); Hung-Lin CHEN, Hsinchu (TW); Hsuan-Cheng KUO, Hsinchu (TW)

(21) Appl. No.: 19/011,911

(22) Filed: Jan. 7, 2025

(51) Int. Cl. H01L 23/40; H01L 21/48; H01L 23/367; H01L 23/538; H01L 25/07

(52) U.S. Cl. CPC H10W 40/613; H10W 40/037; H10W 40/22; H10W 70/611; H10W 90/00; H10W 90/401; H10W 90/288

(57) ABSTRACT

A multiple cold plate structure and methods for forming the same. In some embodiments, the structure includes a first component, and a second component attached to an interposer. The first component may have a thickness that differs from that of the second component. The structure includes a first contact plate attached to a top surface of the first component and a second contact plate attached to a top surface of the second component. The thickness of the first and second contact plates differ and are selected so that the top surface of the first contact plate and the second contact plate are substantially co-planar with one another. In some embodiments, the structure optionally includes an upper plate attached to the top surfaces of the first contact plate and the second contact plate.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

A system on wafer (SoW) is an advanced packaging method that integrates multiple components onto a single wafer, enhancing performance and reducing overall size. Due to the high density of integrated components, the SoW may produce large amounts of heat. A cold plate may be included in the SoW to provide efficient thermal dissipation and effectively maintain optimal operating temperatures.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an example vertical cross-sectional view of an SoW including a separated contact plate structure according to various embodiments.

FIG. 1B is an example vertical cross-sectional view of an SoW including an alternative separated contact plate structure according to various embodiments.

FIG. 1C is an example vertical cross-sectional view of an SoW including a further alternative separated contact plate structure according to various embodiments.

FIG. 2A is an example vertical cross-sectional view of an intermediate structure in a process of forming interposers on a first carrier substrate according to various embodiments.

FIG. 2B is a top-down view of the region of the intermediate structure of FIG. 2A.

FIG. 3A is an example vertical cross-sectional view of an intermediate structure in a process of forming redistribution-side bonding structures and first solder material portions according to various embodiments.

FIG. 3B is a top-down view of the region of the intermediate structure of FIG. 3A.

FIG. 4A is an example vertical cross-sectional view of an intermediate structure in a process of attaching semiconductor dies in an SoW according to various embodiments.

FIG. 4B is a top-down view of the region of the intermediate structure of FIG. 4A.

FIG. 4C is a magnified vertical cross-sectional view of a high bandwidth memory die.

FIG. 5 is an example vertical cross-sectional view of an intermediate structure in a process of forming die-side underfill material portions of an SoW according to various embodiments.

FIG. 6A is an example vertical cross-sectional view of an intermediate structure in a process of forming a molding material of an SoW according to various embodiments.

FIG. 6B is a top-down view of the region of the intermediate structure of FIG. 6A.

FIG. 7 is an example vertical cross-sectional view of an intermediate structure in a process of attaching a second carrier substrate and detaching the first carrier substrate in an SoW according to various embodiments.

FIG. 8 is an example vertical cross-sectional view of an intermediate structure in a process of forming interposer bonding pads of an SoW according to various embodiments.

FIG. 9 is an example vertical cross-sectional view of an intermediate structure in a process of detaching the second carrier substrate of an SoW according to various embodiments.

FIG. 10A is an example vertical cross-sectional view of an intermediate structure in a process of attaching components of an SoW according to various embodiments.

FIG. 10B is a top-down view of the intermediate structure of FIG. 10A.

FIG. 11 is an example vertical cross-sectional view of an intermediate structure in a process of attaching a cold plate in an SoW according to various embodiments.

FIG. 12A is an example vertical cross-sectional view of an intermediate structure in a process of attaching a first contact plate of an SoW according to various embodiments.

FIG. 12B is a top-down view of the intermediate structure of FIG. 12A.

FIG. 13A is an example vertical cross-sectional view of an intermediate structure in a process of forming a fastener cavity for the first contact plate in an SoW according to various embodiments.

FIG. 13B is an example vertical cross-sectional view of an intermediate structure in a process of securing the contact plate with fasteners according to various embodiments.

FIG. 13C is a top-down view of the intermediate structure of FIG. 13B.

FIG. 14A is an example vertical cross-sectional view of an intermediate structure in a process of attaching a second contact plate in an SoW according to various embodiments.

FIG. 14B is a top-down view of the intermediate structure of FIG. 14A.

FIG. 15A is an example vertical cross-sectional view of an intermediate structure in a process of forming fastener cavities for the second plate in an SoW according to various embodiments.

FIG. 15B is an example vertical cross-sectional view of an intermediate structure in a process of securing the second contact plate with fasteners in an SoW according to various embodiments.

FIG. 15C is a top-down view of the intermediate structure of FIG. 15B.

FIG. 16A is an example vertical cross-sectional view of an intermediate structure in a process of attaching an upper plate over the first and second contact plates in an SoW according to various embodiments.

FIG. 16B is a top-down view of the intermediate structure of FIG. 16A.

FIG. 17 is a flowchart illustrating a method of forming an SoW that includes a separated contact plate structure according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments relate to a separated contact plate structure for semiconductor packages, such as SoW packages, to provide effective thermal dissipation across all components. Various embodiments address the challenge of non-uniform thickness among various components. For examples, Voltage Regulator Modules (VRMs) and connectors, tend to be thinner than computation integrated circuit components on the same SoW. By introducing separated top contact plates, each having a thickness based on the thickness of underlying components, various embodiments provide effective thermal dissipation across all components. Various embodiments may increase the overall heat capacity of the SoW by providing efficient thermal contact between contact plates and components. Various embodiments provide fabrication flexibility to provide adjustment of contact stress through bolts to further enhance the thermal conductivity, making the system adaptable to different component needs. As a result, various embodiments may enhance the efficiency, reliability, and longevity of semiconductor packages by maintaining optimal operating temperatures.

A cold plate in a System on Wafer (SoW) package is essential for managing the heat generated by the densely packed electronic components integrated onto a single wafer. The cold plate is typically made from materials with high thermal conductivity, such as copper or aluminum, which help in quickly absorbing and transferring heat away from the components within the SoW. The cold plates often feature intricate channel designs, such as U-turns or serpentine patterns, to maximize the surface area for heat transfer from components to the cold plate, with liquid cooling being a common method of removing heat from the cold plate.

However, a challenge with a related cold plate is the inability to uniformly attach to components with varying thicknesses, which is common in semiconductor packages that include different types of components. For example, a semiconductor package may include a VRM with a height larger than an adjacent connector. A cold plate with uniform thickness may make good thermal contact with the VRM, but poor thermal contact with the connector. This non-uniform thermal contact may lead to inefficient heat dissipation and potential thermal hotspots.

To address this, related methods include thermal interface materials (TIMs) to fill gaps so as to improve thermal conductivity; however, TIMs may not fully resolve the problem. TIMs may only compensate for minor thickness differences, and in instances in which semiconductor packages include components with substantial thickness disparities, TIMs introduce thermal resistance that impedes efficient heat transfer. Additionally, TIMs may lack the mechanical stability needed to maintain consistent contact over time, leading to degradation or shifting under thermal cycling and mechanical stress. This results in reduced heat dissipation efficiency and long-term reliability issues. Further, relying on TIMs to bridge large gaps complicates the manufacturing process and increases costs, making it less practical compared to solutions that provide direct thermal contact. Overall, while TIMs are useful for minor surface irregularities, they are not sufficient for managing the large thickness variations in semiconductor packages.

Consequently, SoW components with lower thicknesses may suffer from inadequate heat dissipation, leading to potential performance and reliability issues. Providing consistent and effective thermal dissipation for all components in an SoW is crucial for enhancing the efficiency and longevity of semiconductor packages. The disparity in thicknesses has posed a problem for related cooling solutions, as related cold plates may not uniformly attach to all components.

Various embodiments provide separated contact cold plate structures and assemblies configured with thicknesses that provide consistent thermal contact with all components thereby enhancing overall thermal management of a semiconductor package.

In some embodiments, a semiconductor structure includes separated contact plates that provide efficient thermal contact between contact plates and components, even in the instance of components having differing heights. The semiconductor structure may include a first component, and a second component attached to an interposer, in which the first component may have a first thickness and that differs from a second thickness of the second component. A first contact plate may be attached to a top of the first component and a second contact plate may be attached to the top of the second component thereby enabling proper thermal contact between contact plates and components. The two contact plates may have thicknesses that provide the top of the first contact plate and the second contact plate to be co-planar or at least substantially co-planar when positioned on respective components. The contact plates may be connected to a bottom surface of the SoW structure by fasteners, such as bolts that apply a compression force between the contact plates and components. In some embodiments, an upper plate may be attached above and in thermal contact with the first and second contact plate. The upper plate may be secured to the first and second contact plates using an adhesive. In instances in which a third component with a different thickness is attached to the interposer, a third contact plate may be attached to the third component with a thickness that provides the top of the third contact plate to be co-planar or at least substantially co-planar with the first and second contact plates to provide proper thermal contact between contact plates and components.

In a further embodiment, the separated contact plate structure may be formed by a method that provides proper thermal contact between a contact plate assembly and various components with differing heights. The method may include attaching a first component and a second component to a surface of an interposer. The method may include determining a height of the first component and a height of the second component and selecting a first contact plate and a second contact plate based on the height of the first and second component, respectively. The method may further include attaching a first contact plate to a the top of the first component and attaching a second contact plate to the top of the second component. The first component and second component may have differing thicknesses. Based on each component's height, the first contact plate and the second contact plate may be fabricated or selected from a plurality of prefabricated plates based on the component thicknesses so that the tops are co-planar when the SoW is assembled. In some embodiments, the method includes forming fastener cavities for fasteners to connect to a bottom portion of the SoW structure for applying a compression force between the first contact plate and the first component and applying a compression force between the second contact plate and the second component ensuring direct thermal contact between components 1000/1050 and contact plates 1120/1140 to ensure efficient heat transfer therebetween. An upper plate may optionally be attached above the first and second contact plate and secured using an adhesive.

Various embodiments provide multiple advantages and improvements. For example, various embodiments include separated contact plate structures that may provide effective thermal contact with components thereby enhancing overall thermal dissipation efficiency. Additionally, various embodiments may increase heat capacity of cold plates thereby improving thermal management. The additional cold plates may further allow for precise adjustment of contact stress to provide optimal thermal contact and performance. Various embodiments may provide uniform thermal distribution across components with varying thicknesses and prevent hotspots by providing consistent cooling. Further, various embodiments may maintain operating temperatures for all components regardless of their thickness, thereby enhancing thermal management and reliability. Various embodiments may include design flexibility by allowing for adjustable contact stress through bolts or adhesives and providing flexibility to tailor cooling solutions to specific component needs. Various embodiments may also be expanded to multiple technology generations, applications, components, and cooling methods due to the flexibility, adaptability, and versatility of the separated contact plates. As a result, various embodiments may extend the operational lifespan of a semiconductor package.

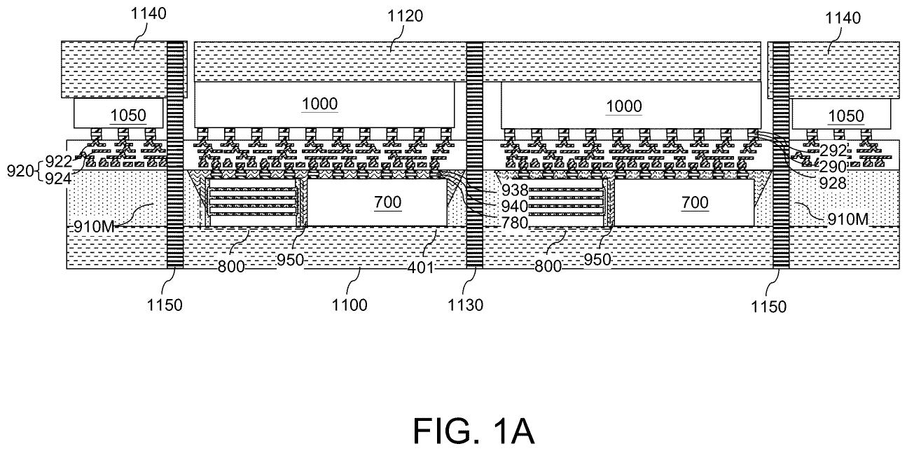

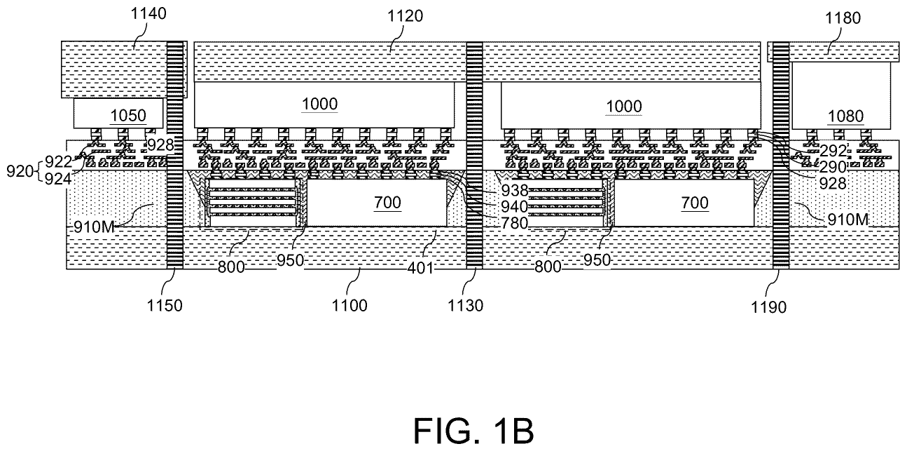

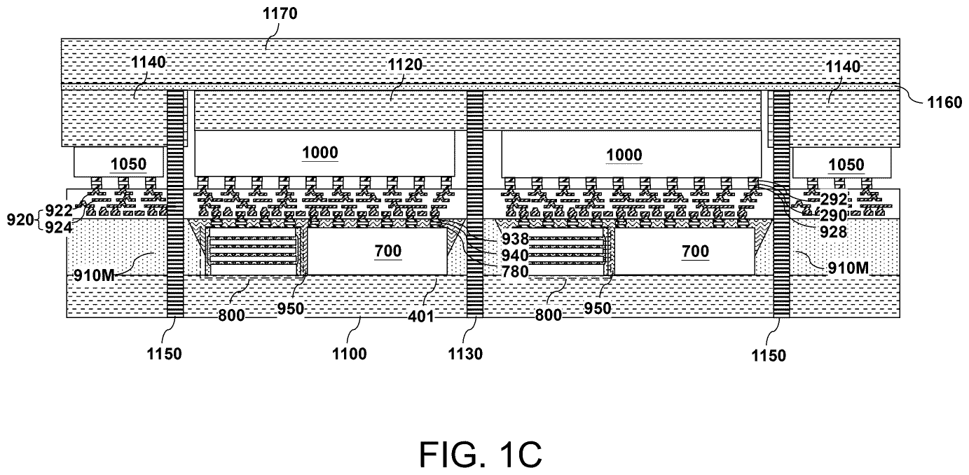

Referring to FIG. 1A, a semiconductor structure in the form of an SoW or other integrated circuit package may include an interposer 920 connected to a plurality of semiconductor dies such as a high bandwidth memory (HBM) 800 and a system on chip (SoC) 700. In some embodiments, the semiconductor dies 700/800 may be surrounded by a molding 910M and an underfill material 950. The semiconductor dies 700/800 may be attached to the interposer through die side bonding structures 780 attached to a solder material 940 and further attached to an redistribution side bonding structure 938 thereby creating a vertical electrical connection between the interposer 920 and semiconductor dies 700/800. Further, in some embodiments, a bottom surface cold plate 1100 may be attached below the semiconductor dies 700/800 and molding compound 910M to provide efficient heat transfer between the semiconductor dies 700/800 and the bottom surface cold plate 1100 to support thermal management during operation.

Attached to a top surface of the interposer 920 are components 1000/1050. In some embodiments, component 1000 may be a VRM and component 1050 may be a connector. Other components are within the contemplated scope of the disclosure. The components 1000/1050 may be electrically connected or attached to the interposer 920 by component bonding structures 292 connected to solder material portions 290 further connected to interposer bonding pads 928.

In some embodiments, the components 1000/1050 may have varying thicknesses. For example, as shown, component 1000 (e.g., a VRM) may be thicker than component 1050 (e.g., a connector). Due to the varying thicknesses, the various components will have top surfaces that are not co-planar when the SoW is assembled. Traditional top surface cold plate structures may fail to make appropriate contact with thinner components (e.g., thinner component 1050), thereby decreasing heat conduction between the thinner component 1050 and the cold plate. As a result, traditional top surface cold plates lose contact with components with smaller thicknesses and lose heat conduction pathways, which may impact performance by increasing component temperatures during operation.

Referring back to FIG. 1A, separated contact plates 1120/1140 may be attached to the components 1000/1050 of varying thicknesses thereby ensuring proper thermal contact between the contact plates 1120/1140 and the components 1000/1050 that have different thicknesses. Using different contact plates in this manner may improve heat conduction pathways between all components and improve heat dissipation performance.

In some embodiments, each contact plate 1120/1140 may be a cold plate such as micro-channel, brazed, press-fit, tube-in-plate, friction stir welded (FSW), vacuum brazed, pin fin, and direct liquid cooling plates. Micro-channel cold plates feature numerous small channels for efficient heat transfer, ideal for high-power density applications. Brazed cold plates are constructed by bonding multiple metal layers, offering strong, leak-free construction and excellent thermal performance. Press-fit cold plates are designed for easy installation and removal, creating a secure thermal interface without complex fasteners. Tube-in-plate cold plates have small tubes embedded within a metal plate, allowing for efficient heat transfer in space-constrained applications. FSW cold plates are made from aluminum and are suitable for high-power cooling needs, especially with glycol-water mixtures. Vacuum brazed cold plates provide high thermal performance and precise temperature control. Pin fin cold plates feature a series of pins that increase the surface area for heat dissipation. Direct liquid cooling plates bring the cooling fluid in direct contact with the heat source, ensuring efficient heat transfer and precise temperature control. In some embodiments, the contact plate 1120 and the contact plate 1140 have different thicknesses, but may be the same type of cold plate or different types of cold plates based on the needs of the semiconductor structure.

The contact plates 1120/1140 may be configured to have top surfaces that are substantially co-planar provided by the contact plates 1120/1140 having thicknesses that differ based on the height or thickness of the underlying components 1000/1050. The fasteners 1130/1150 may connect to a bottom of the SoW structure thereby applying compression forces between the contact plates 1120/1140 and the components 1000/1050. In some embodiments, the fasteners are bolts, screws, or other appropriate fasteners. The fasteners may have a diameter of about 6 mm to about 8 mm. The fasteners 1130/1150 may be tightened or loosened to adjust contact stress between the contact plates 1120/1140 and the components 1000/1050. For example, more contact stress may be applied to increase thermal bonding between contact plate 1120 and component 1000, while less stress is applied between contact plate 1140 and component 1050 which may generate less heat or be vulnerable to stress forces. Therefore, contact stress plates and components may be adjusted or controlled based on the needs of the semiconductor structure.

FIG. 1B shows an alternative embodiment of the semiconductor structure with a separated contact plate structure. As shown, the semiconductor structure may include a third component 1080 on top of which is positioned a third contact plate 1180. The third component 1080 may have a thickness that differs from components 1000/1050. For example, component 1080 may be thicker than component 1000 which is thicker than component 1050, in which case the third contact plate 1180 may be thinner than the first contact plate 1120 which may be thinner than the second contact plate 1140 so that the tops of the contact plates are co-planar or at least substantially co-planar in the assembled semiconductor structure. The third contact plate 1180 may be attached to the third component 1080 by a third fastener 1190.

While two and three components are shown in FIG. 1A and FIG. 1B, respectively, embodiments with more than three components are within the contemplated scope of the disclosure. Similarly, while contact plates 1120/1140/1180 with fasteners 1150/1130/1190 are described, more or fewer contact plates and/or fasteners are also within the contemplated scope of the disclosure. More or fewer contact plates may be used to provide proper contact between components and contact plates, thereby improving heat dissipation performance due to improved attachment between elements.

FIG. 1C shows another embodiment that includes an upper plate 1170 that may be thermally bonded to the top of the contact plates 1120/1140. In some embodiments, the upper plate 1170 may be a cold plate such as a micro-channel, brazed, press-fit, tube-in-plate, FSW, vacuum brazed, pin fin, and direct liquid cooling plates, while the contact plates 1120/1140 provide thermal conduction between components and the upper plate. The addition of the upper plate 1170 may further improve heat capacity by providing additional cooling in instances in which designs using the contact plates 1120/1140 fail to meet thermal performance requirements alone.

In some embodiments, the upper plate 1170 may be attached by an adhesive 1160 such as a gel thermal interface material (TIM). The gel TIM may enhance thermal conductivity between contact plates and the upper plate. Silicone-based TIM adhesives contain thermally conductive fillers that facilitate efficient heat transfer. Gel TIM adhesives exhibit high thermal conductivity, which makes them suitable for high-performance applications. TIMs exhibit flexibility and conformability, allowing them to fill gaps and provide a good thermal interface between the upper plate and the contact plates. Additionally, once cured, TIM adhesives maintain their thermal and mechanical properties over a wide range of temperatures.

In some embodiments, holes (not shown) may be formed within the upper plate 1170 by drilling or etching to allow access to the fasteners 1130/1150. By allowing access to the fasteners 1130/1150 through the upper plate 1170, the fasteners 1130/1150 may be loosened or tightened after assembly or in the aftermarket, and the upper plate 1170 and/or contact plates 1120/1140 may be removed for service, and maintenance, or replacement in instances in which damage occurs.

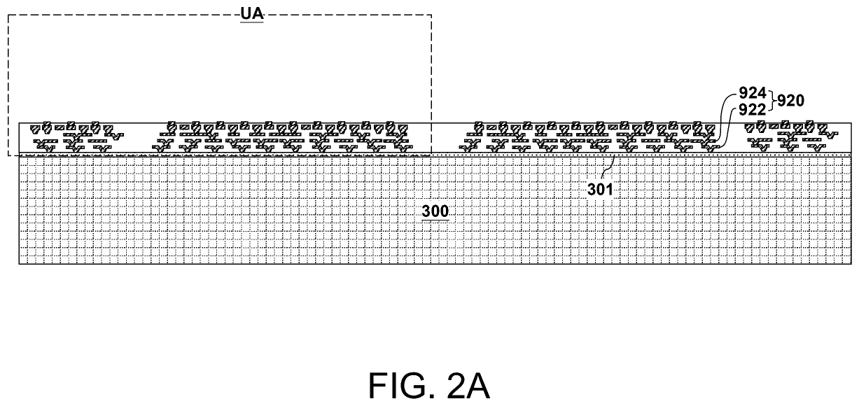

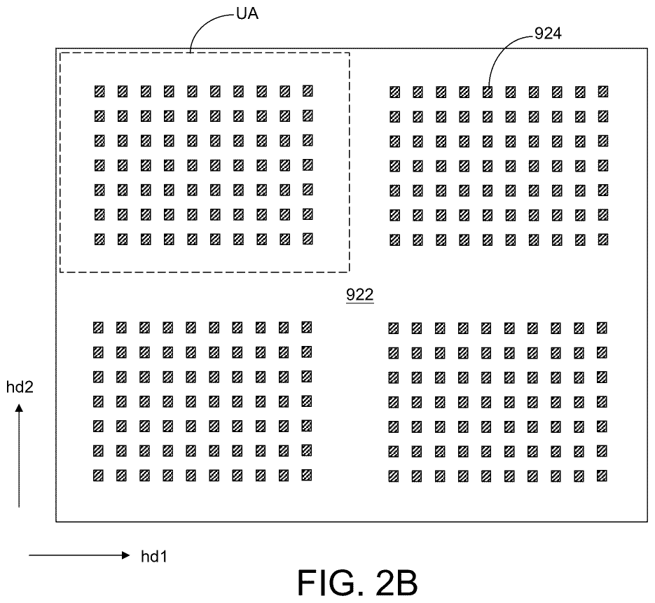

Referring to FIGS. 2A and 2B, an intermediate structure of the SoW or semiconductor structure according to some embodiments may include a first carrier substrate 300 and interposers 920 formed on a front side surface of the first carrier substrate 300. The first carrier substrate 300 may include an optically transparent substrate, such as a glass substrate or a sapphire substrate. The diameter of the first carrier substrate 300 may be in a range from 150 mm to 290 mm, although lesser and greater diameters may be used. In addition, the thickness of the first carrier substrate 300 may be in a range from 500 microns to 2,000 microns, although smaller and larger thicknesses may also be used. Alternatively, the first carrier substrate 300 may be provided in a rectangular panel format. The dimensions of the first carrier in such alternative embodiments may be substantially the same.

A first adhesive layer 301 may be applied to the front-side surface of the first carrier substrate 300. In some embodiments, the first adhesive layer 301 may be a light-to-heat conversion (LTHC) layer. The LTHC layer may be a solvent-based coating applied using a spin coating method. The LTHC layer may convert ultraviolet light to heat, which may cause the material of the LTHC layer to lose adhesion. Alternatively, the first adhesive layer 301 may include a thermally decomposing adhesive material. For example, the first adhesive layer 301 may include an acrylic pressure-sensitive adhesive that decomposes at an elevated temperature. The debonding temperature of the thermally decomposing adhesive material may be in a range from 150° C. to 200° C.

Redistribution structures 920 may be formed over the first adhesive layer 301. The redistribution structures may provide electrical connections between different layers of the SoW structure. Specifically, an interposer 920 may be formed within each unit area UA, which is the area of a repetition unit that may be repeated in a two-dimensional array over the first carrier substrate 300. Each interposer 920 may include redistribution dielectric layers 922 and redistribution wiring interconnects 924. The redistribution dielectric layers 922 include a respective dielectric polymer material such as polyimide (PI), benzocyclobutene (BCB), or polybenzobisoxazole (PBO). Other suitable materials may be within the contemplated scope of disclosure. Each redistribution dielectric layer 922 may be formed by spin coating and drying of the respective dielectric polymer material. The thickness of each redistribution dielectric layer 922 may be in a range from 2 microns to 40 microns, such as from 4 microns to 20 microns. Each redistribution dielectric layer 922 may be patterned, for example, by applying and patterning a respective photoresist layer thereabove, and by transferring the pattern in the photoresist layer into the redistribution dielectric layer 922 using an etch process such as an anisotropic etch process. The photoresist layer may be subsequently removed, for example, by ashing.

Each of the redistribution wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 400 nm, and the copper seed layer may have a thickness in a range from 100 nm to 500 nm. The metallic fill material for the redistribution wiring interconnects 924 may include copper, nickel, or copper and nickel. Other suitable metallic fill materials are within the contemplated scope of disclosure. The thickness of the metallic fill material that is deposited for each redistribution wiring interconnect 924 may be in a range from 2 microns to 40 microns, such as from 4 microns to 10 microns, although thicknesses that are thinner or thicker than this range may be used. The total number of levels of wiring in each interposer 920 (i.e., the levels of the redistribution wiring interconnects 924) may be in a range from 1 to 10. A periodic two-dimensional array (such as a rectangular array) of interposers 920 may be formed over the first carrier substrate 300. Each interposer 920 may be formed within a unit area UA. The layer including all interposers 920 is herein referred to as an interposer layer. The interposer layer includes a two-dimensional array of interposers 920. In one embodiment, the two-dimensional array of interposers 920 may be a rectangular periodic two-dimensional array of interposers 920 having a first periodicity along a first horizontal direction hd1 and having a second periodicity along a second horizontal direction hd2 that is perpendicular to the first horizontal direction hd1.

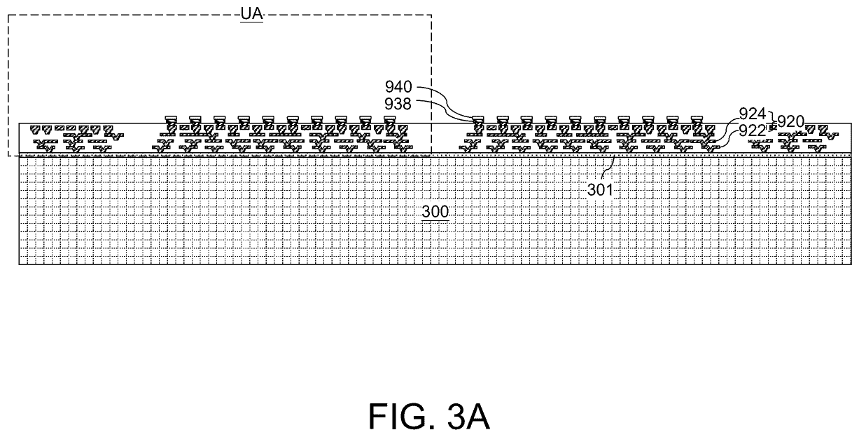

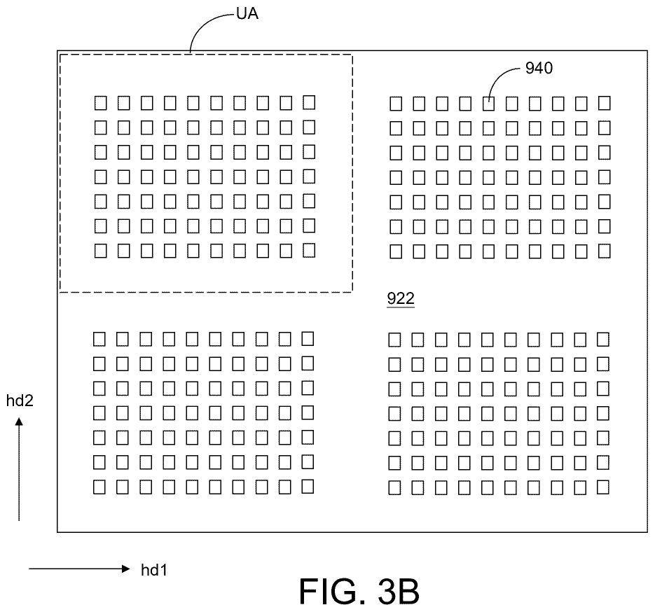

Referring to FIGS. 3A and 3B, at least one metallic material and a first solder material may be sequentially deposited over the front-side surface of the interposers 920. The at least one metallic material may include a material that may be used for metallic bumps, such as copper. The thickness of the at least one metallic material may be in a range from 5 microns to 60 microns, such as from 10 microns to 30 microns, although lesser and greater thicknesses may also be used. The first solder material may include a solder material suitable for C2 bonding, i.e., for microbump bonding. The thickness of the first solder material may be in a range from 2 microns to 30 microns, such as from 4 microns to 15 microns, although lesser and greater thicknesses may also be used.

The first solder material and the at least one metallic material may be patterned into discrete arrays of first solder material portions 940 and arrays of metal bonding structures, which are herein referred to as arrays of redistribution-side bonding structures 938. Each array of redistribution-side bonding structures 938 is formed within a respective unit area UA. Each array of first solder material portions 940 is formed within a respective unit area UA. Each first solder material portion 940 may have the same horizontal cross-sectional shape as an underlying redistribution-side bonding structures 938.

In some embodiments, the redistribution-side bonding structures 938 may include copper or a copper-containing alloy. Other suitable materials are within the contemplated scope of disclosure. The thickness of the redistribution-side bonding structures 938 may be in a range from 5 microns to 60 microns, although thicknesses that are thinner or thicker than this range may be used. The redistribution-side bonding structures 938 may have horizontal cross-sectional shapes of rectangles, rounded rectangles, circles, regular polygons, irregular polygons, or any other two-dimensional curvilinear shape having a closed periphery. In some embodiments, redistribution-side bonding structures 938 may be configured for microbump bonding (i.e., C2 bonding), and may have a thickness in a range from 10 microns to 30 microns, although thicknesses that are thinner or thicker than this range may be used. In some embodiments, each array of redistribution-side bonding structures 938 may be formed as an array of microbumps having a lateral dimension in a range from 10 microns to 25 microns and having a pitch in a range from 20 microns to 50 microns.

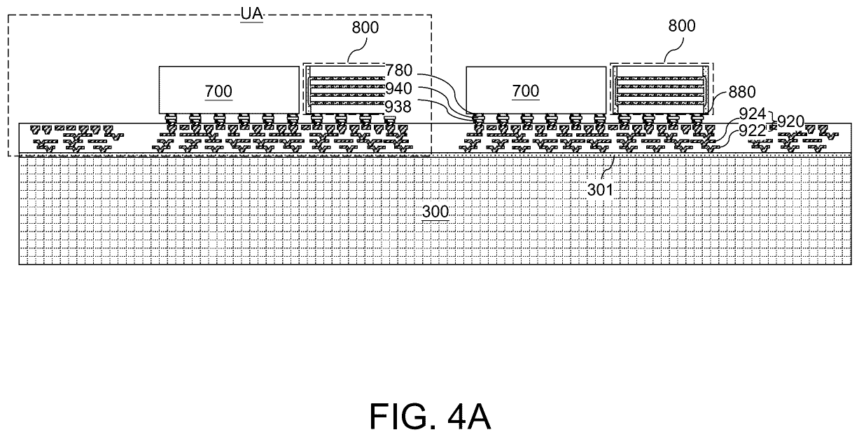

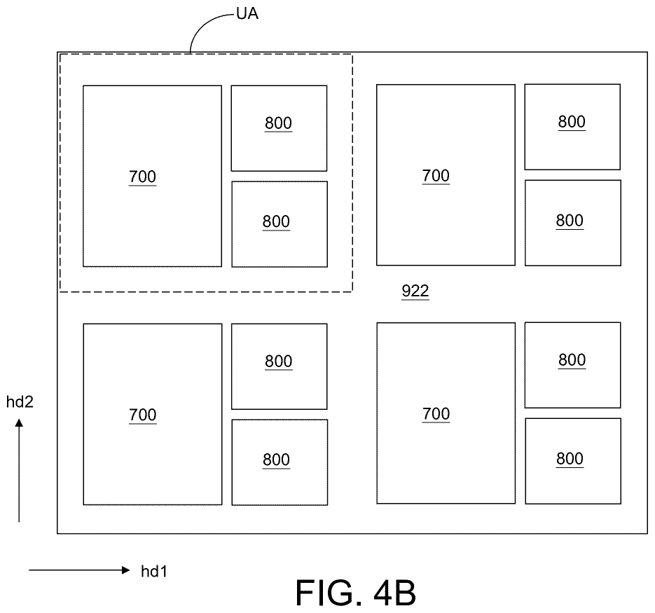

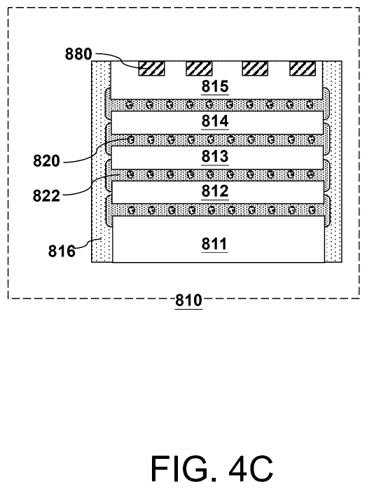

Referring to FIGS. 4A and 4B, a set of at least one semiconductor die 700/800 may be bonded to each interposer 920. In some embodiments, the interposers 920 may be arranged as a two-dimensional periodic array, and multiple sets of at least one semiconductor die 700/800 may be bonded to the interposers 920 as a two-dimensional periodic rectangular array of sets of the at least one semiconductor die 700/800. Each set of at least one semiconductor die 700/800 includes at least one semiconductor die. In some embodiments, each set of at least one semiconductor die 700/800 may include a plurality of semiconductor dies 700/800. For example, each set of at least one semiconductor die 700/800 may include at least one SoC die 700 and/or at least one memory die 800. Each SoC die 700 may include an application processor die, a central processing unit die, or a graphic processing unit die. In some embodiments, the at least one memory die 800 may include a high bandwidth memory (HBM) die that includes a vertical stack of static random access memory dies. In some embodiments, the at least one semiconductor die 700/800 may include at least one SoC die and a high bandwidth memory (HBM) die including a vertical stack of static random access memory (SRAM) dies that are interconnected to one another through microbumps and are laterally surrounded by an epoxy molding material enclosure frame.

Each semiconductor die 700/800 may include a respective array of die-side bonding structures 780/880. For example, each SoC die 700 may include an array of SoC metal bonding structures 780, and each memory die 800 include an array of memory-die metal bonding structures 880. Each of the semiconductor dies 700/800 may be positioned in a face-down position such that die-side bonding structures 780/880 face the first solder material portions 940. Each set of at least one semiconductor die 700/800 may be placed within a respective unit area UA. Placement of the semiconductor dies 700/800 may be performed using a pick and place (PnP) apparatus such that each of the die-side bonding structures 780/880 may be placed on a top surface of a respective one of the first solder material portions 940.

Generally, an interposer 920 including redistribution-side bonding structures 938 thereupon may be provided, and at least one semiconductor die 700/800 including a respective set of die-side bonding structures 780/880 may be provided. The at least one semiconductor die 700/800 may be bonded to the interposer 920 using first solder material portions 940 that are bonded to a respective redistribution-side bonding structure 938 and to a respective one of the die-side bonding structures 780/880. Each set of at least one semiconductor die 700/800 may be attached to a respective interposer 920 through a respective set of first solder material portions 940.

Referring to FIG. 4C, a high bandwidth memory (HBM) die 810 is illustrated, which may be used as a memory die 800 within the first intermediate structures of FIGS. 4A and 4B. The HBM die 810 may include a vertical stack of static random access memory dies 811/812/813/814/815 that are interconnected to one another through microbumps 820 and are laterally surrounded by an epoxy molding material enclosure frame 816. The gaps between vertically neighboring pairs of the random access memory dies 811/812/813/814/815 may be filled with an HBM underfill material portions 822 that laterally surrounds a respective set of microbumps 820. The HBM die 810 may include an array of memory-die metal bonding structures 880 configured to be bonded to a subset of an array of redistribution-side bonding structures 938 within a unit area UA.

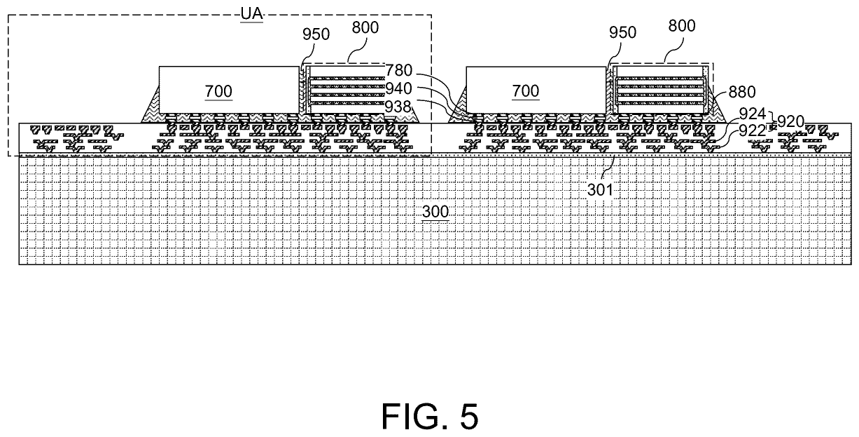

Referring to FIG. 5, a die-side underfill material may be applied into each gap between the interposers 920 and sets of at least one semiconductor die 700/800 that are bonded to the interposers 920. A die-side underfill material portion 950 may be formed within each unit area UA between an interposer 920 and an overlying set of at least one semiconductor die 700/800. The die-side underfill material portions 950 may be formed by injecting the die-side underfill material around a respective array of first solder material portions 940 in a respective unit area UA. The underfill material portion 950 may be formed by a capillary underfill method, a molded underfill method, or a printed underfill method.

Within each unit area UA, a die-side underfill material portion 950 may laterally surround, and contact, each of the first solder material portions 940 within the unit area UA. The die-side underfill material portion 950 may be formed around and contact the first solder material portions 940, the redistribution-side bonding structures 938, and the die-side bonding structures 780/880 in the unit area UA.

Each interposer 920 in a unit area UA includes redistribution-side bonding structures 938. At least one semiconductor die 700/800 including a respective set of die-side bonding structures 780/880 is attached to the redistribution-side bonding structures 938 through a respective set of first solder material portions 940 within each unit area UA. Within each unit area UA, a die-side underfill material portion 950 laterally surrounds the redistribution-side bonding structures 938 and the die-side bonding structures 780/880 of the at least one semiconductor die 700/800.

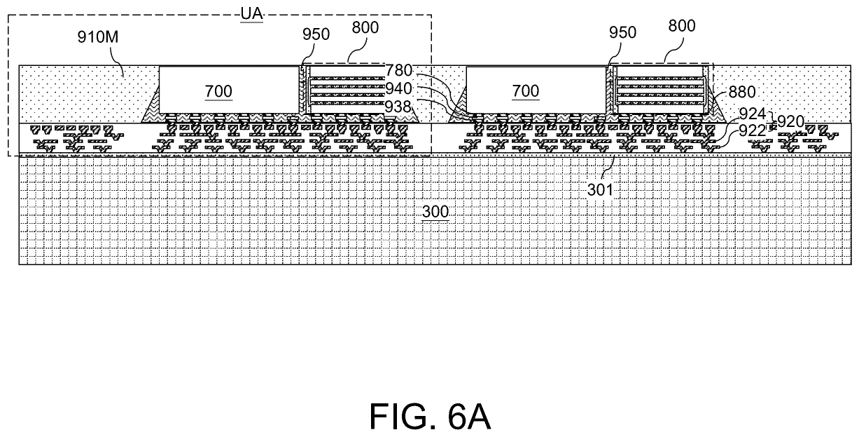

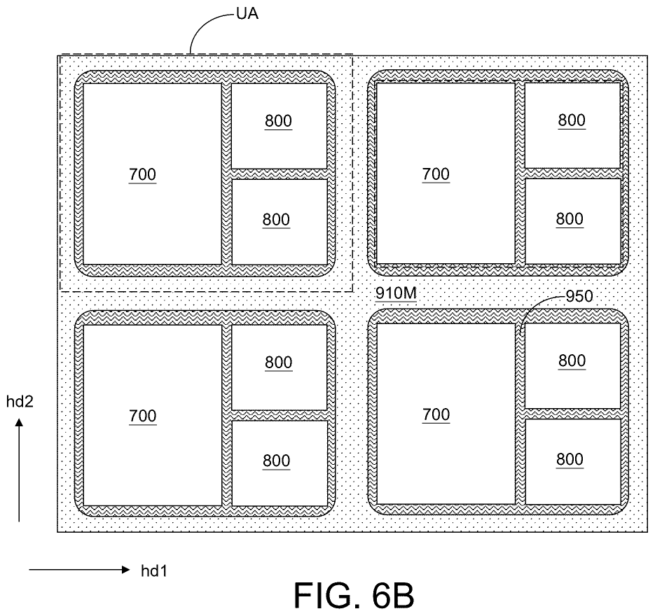

Referring to FIGS. 6A and 6B, an epoxy molding compound (EMC) may be applied to the gaps between contiguous assemblies of a respective set of semiconductor dies 700/800 and a die-side underfill material portion 950.

The EMC may include an epoxy-containing compound that may be hardened (i.e., cured) to form a dielectric material portion that provides stiffness and mechanical strength. The EMC may include epoxy resin, hardener, silica (as a filler material), and other additives. The EMC may be provided in a liquid form or in a solid form depending on the viscosity and flowability. Liquid EMC provides better handling, good flowability, less voids, better fill, and less flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks and may enhance flowability. The curing temperature of the EMC may be lower than the release (debonding) temperature of the first adhesive layer 301 in embodiments in which the adhesive layer includes a thermally debonding material. For example, the curing temperature of the EMC may be in a range from 125° C. to 150° C.

The EMC may be cured at a curing temperature to form an EMC matrix or a molding 910M that laterally surrounds and embeds each assembly of a set of semiconductor dies 700/800 and a die-side underfill material portion 950. The molding 910M includes a plurality of epoxy molding compound (EMC) die frames that may be laterally adjoined to one another. Each EMC die frame is a portion of the molding 910M that is located within a respective unit area UA. Thus, each EMC die frame laterally surrounds and embeds a respective a set of semiconductor dies 700/800 and a respective die-side underfill material portion 950. Young's modulus of pure epoxy is about 3.35 GPa, and Young's modulus of the EMC may be higher than Young's modulus of pure epoxy by adding additives. Young's modulus of EMC may be greater than 3.5 GPa.

Portions of the molding 910M that overlies the horizontal plane including the top surfaces of the semiconductor dies 700/800 may be removed by a planarization process. For example, the portions of the molding 910M that overlies the horizontal plane may be removed using a chemical mechanical planarization (CMP) process. The combination of the remaining portion of the molding 910M, the semiconductor dies 700/800, the die-side underfill material portions 950, and the two-dimensional array of interposers 920 forms a reconstituted wafer. Each portion of the molding 910M located within a unit area UA constitutes an EMC die frame.

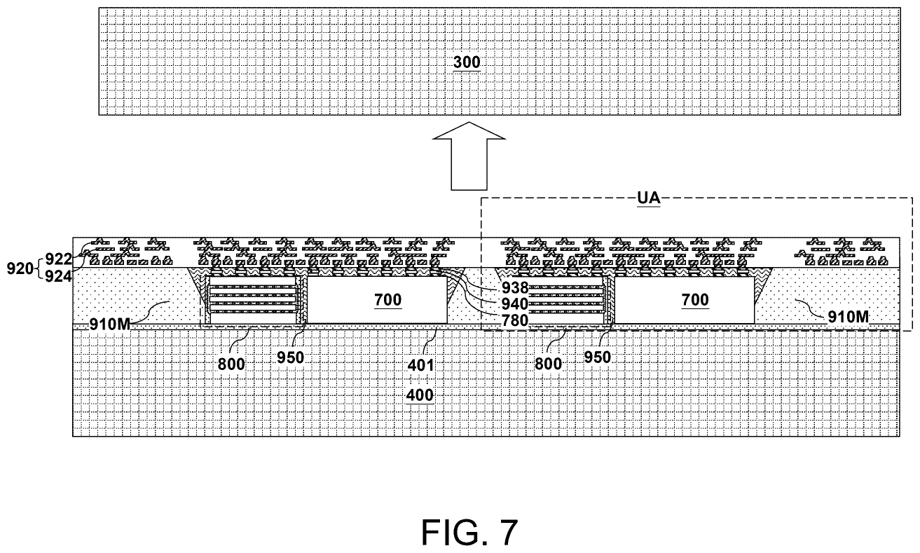

Referring to FIG. 7, a second adhesive layer 401 may be applied to the physically exposed planar surface of the reconstituted wafer, i.e., the physically exposed surfaces of the molding 910M, the semiconductor dies 700/800, and the die-side underfill material portions 950. In some embodiments, the second adhesive layer 401 may include a same material as, or may include a different material from, the material of the first adhesive layer 301. In some embodiments in which the first adhesive layer 301 includes a thermally decomposing adhesive material, the second adhesive layer 401 may include another thermally decomposing adhesive material that decomposes at a higher temperature or may include a light-to-heat conversion material.

A second carrier substrate 400 may be attached to the second adhesive layer 401. The second carrier substrate 400 may be attached to the opposite side of the reconstituted wafer relative to the first carrier substrate 300. Generally, the second carrier substrate 400 may include any material that may be used for the first carrier substrate 300. The thickness of the second carrier substrate 400 may be in a range from 500 microns to 2,000 microns, although lesser and greater thicknesses may also be used.

The first adhesive layer 301 may be decomposed by ultraviolet radiation or by a thermal anneal at a debonding temperature. In some embodiments in which the first carrier substrate 300 includes an optically transparent material and the first adhesive layer 301 includes an LTHC layer, the first adhesive layer 301 may be decomposed by irradiating ultraviolet light through the transparent carrier substrate. The LTHC layer may absorb the ultraviolet radiation and generate heat, which decomposes the material of the LTHC layer and causes the transparent first carrier substrate 300 to be detached from the reconstituted wafer. In some embodiments in which the first adhesive layer 301 includes a thermally decomposing adhesive material, a thermal anneal process at a debonding temperature may be performed to detach the first carrier substrate 300 from the reconstituted wafer.

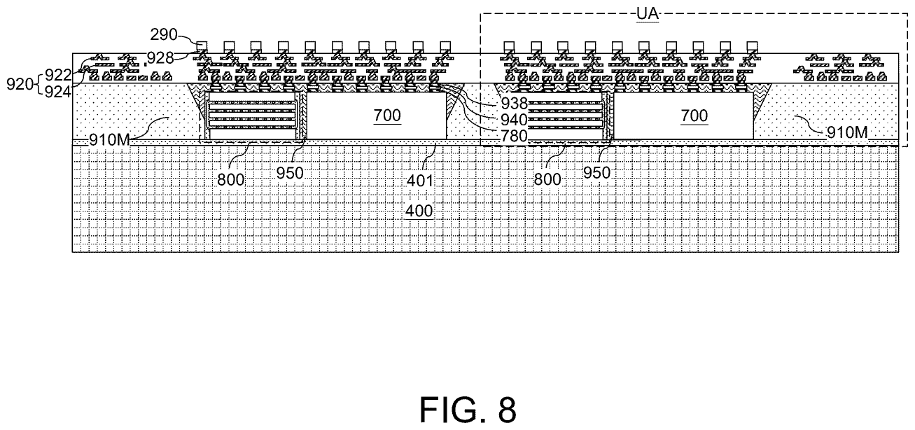

Referring to FIG. 8, interposer bonding pads 928 and second solder material portions 290 may be formed by depositing and patterning a stack of at least one metallic material that may function as metallic bumps and a solder material layer. The metallic fill material for the interposer bonding pads 928 may include copper. Other suitable materials are within the contemplated scope of disclosure. The thickness of the interposer bonding pads 928 may be in a range from 5 microns to 100 microns, although thicknesses that are thinner or thicker than this range may be used. The interposer bonding pads 928 and the second solder material portions 290 may have horizontal cross-sectional shapes of rectangles, rounded rectangles, or circles. Other suitable shapes are within the contemplated scope of the disclosure. In some embodiments in which the interposer bonding pads 928 are formed as C4 (controlled collapse chip connection) pads, the thickness of the interposer bonding pads 928 may be in a range from 5 microns to 50 microns, although thicknesses that are thinner or thicker than this range may be used. In some embodiments, the interposer bonding pads 928 may be, or include, underbump metallization (UBM) structures. The configurations of the interposer bonding pads 928 are not limited to fan-out structures. Alternatively, the interposer bonding pads 928 may be configured for microbump bonding (i.e., C2 bonding), and may have a thickness in a range from 30 microns to 100 microns, although thicknesses that are thinner or thicker than this range may be used. In some embodiments, the interposer bonding pads 928 may be formed as an array of microbumps (such as copper pillars) having a lateral dimension in a range from 10 microns to 25 microns and having a pitch in a range from 20 microns to 50 microns.

The interposer bonding pads 928 and the second solder material portions 290 may be formed on the opposite side of the molding 910M and the two-dimensional array of sets of semiconductor dies 700/800 relative to the interposer layer. The interposer layer includes a three-dimensional array of interposers 920. Each interposer 920 may be located within a respective unit area UA. Each interposer 920 may include redistribution dielectric layers 922, redistribution wiring interconnects 924 embedded in the redistribution dielectric layers 922, and interposer bonding pads 928. The interposer bonding pads 928 may be located on an opposite side of the redistribution-side bonding structures 938 relative to the redistribution dielectric layers 922 and may be electrically connected to a respective one of the redistribution-side bonding structures 938.

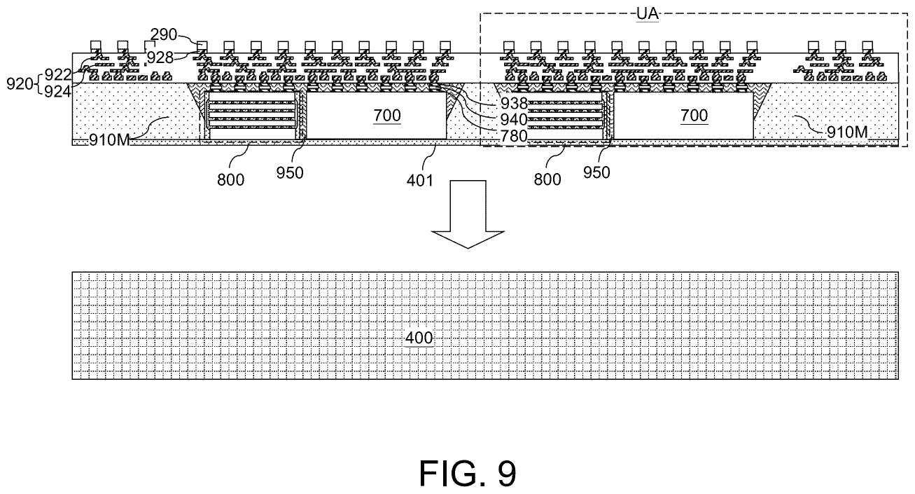

Referring to FIG. 9, the second adhesive layer 401 may be decomposed by ultraviolet radiation or by a thermal anneal at a debonding temperature. In some embodiments in which the second carrier substrate 400 includes an optically transparent material and the second adhesive layer 401 includes an LTHC layer, the second adhesive layer 401 may be decomposed by irradiating ultraviolet light through the transparent carrier substrate. In some embodiments in which the second adhesive layer 401 includes a thermally decomposing adhesive material, a thermal anneal process at a debonding temperature may be performed to detach the second carrier substrate 400 from the reconstituted wafer.

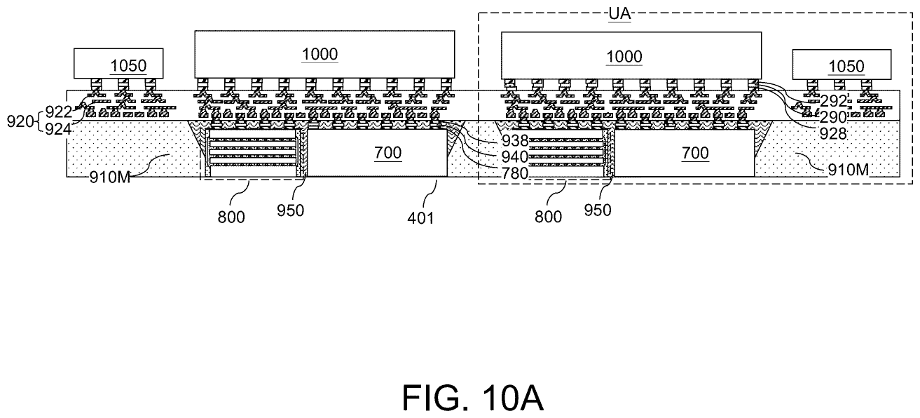

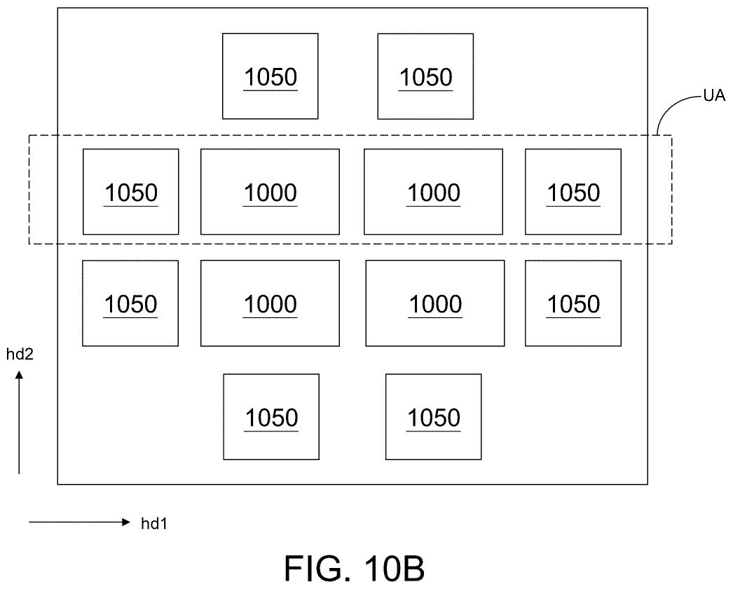

Referring to FIGS. 10A and 10B, a component 1000/1050 may be bonded to the interposer 920. In some embodiments, the interposers 920 may be arranged as a two-dimensional periodic array, and multiple components 1000/1050 may be bonded to the interposers 920 as a two-dimensional periodic rectangular array. The components 1000/1050 may be VRMS, connectors, or other appropriate components. The components 1000/1050 may have different thicknesses. For example, as shown, component 1000 may be thicker than component 1050.

Each component 1000/1050 may include a respective array of component bonding structures 292. Each of the components 1000/1050 may be positioned in a face-up position such that the component bonding structures 292 face the solder material portions 290. A set of components 1000 and component 1050 may be placed within a respective unit area UA. Placement of the components 1000/1050 may be performed using a PnP apparatus such that each of the component bonding structures 292 may be placed on a top surface of a respective one of the solder material portions 290.

Generally, the interposer 920 may include interposer bonding pads 928 and at least one component 1000/1050 including a respective set of component bonding structures. The at least one component 1000/1050 may be bonded to the interposer 920 using solder material portions 290 that are bonded to a respective interposer bonding structure 928 and to a respective one of the component bonding structures 292.

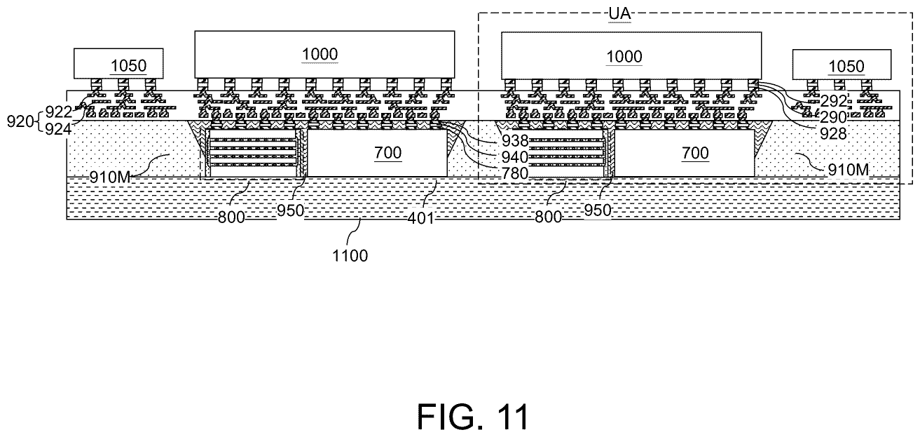

FIG. 11 shows a cold plate 1100 being attached below the molding compound 910M and the semiconductor dies 700/800. In some embodiments, the cold plate 1100 may be a micro-channel, brazed, press-fit, tube-in-plate, FSW, vacuum brazed, pin fin, and direct liquid cooling plates.

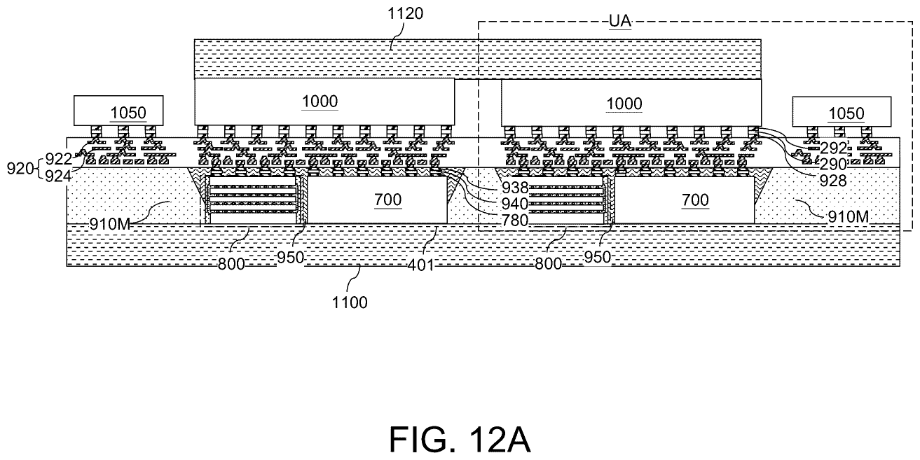

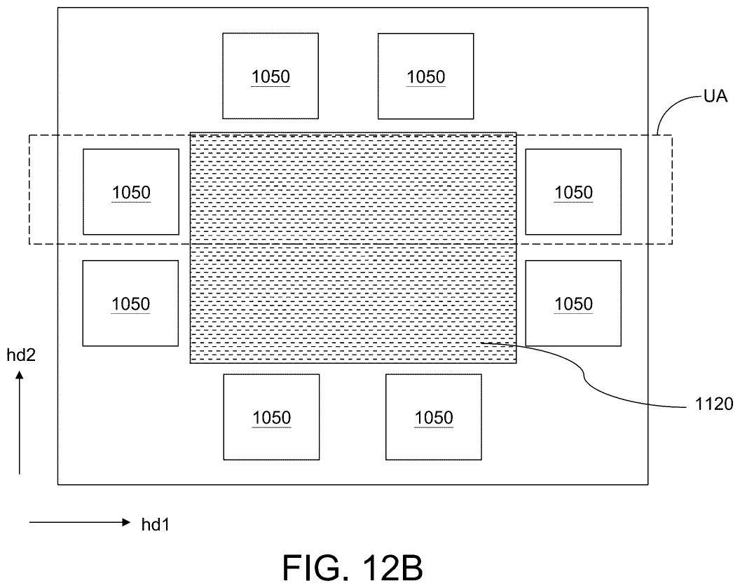

Referring to FIGS. 12A and 12B, a first contact plate 1120 may be attached to the top surface of the components 1000. In some embodiments, the contact plate 1120 may be thermally bonded to the components 1000 using an adhesive, such as a gel TIM. In some embodiments, the contact plate 1120 is wide enough to cover the entirety of components 1000. However, multiple contact plates 1120 or a contact plate 1120 that extends beyond a side boundary of the components 1000 are within the contemplated scope of the disclosure. The contact plate 1120 may have a thickness dependent on the thickness of the components 1000 selected so that the top surface of the plate will be co-planar or at least substantially co-planar with the other contact plates when the semiconductor structure is assembled.

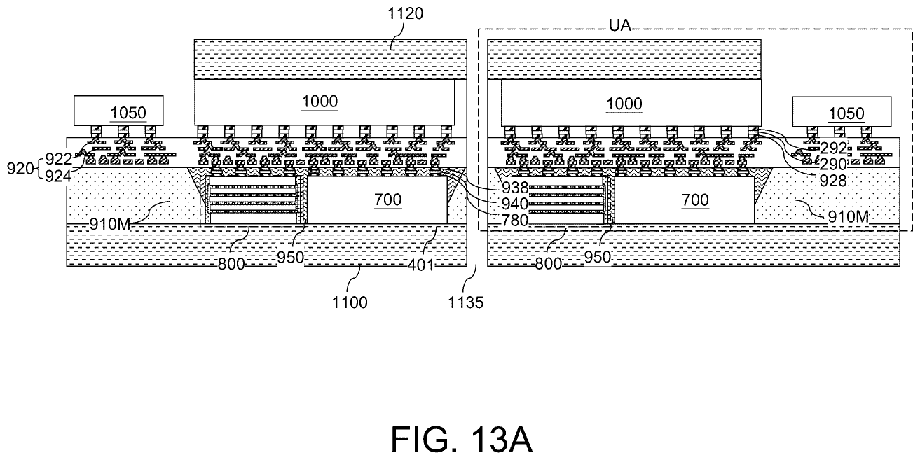

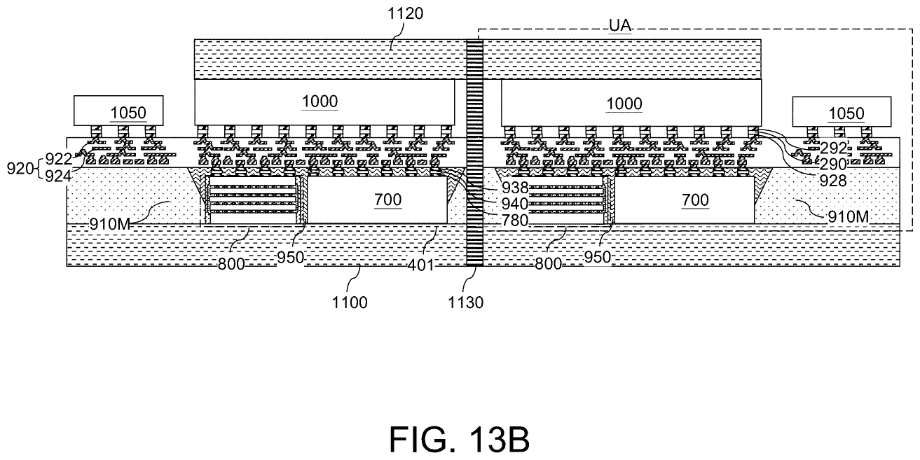

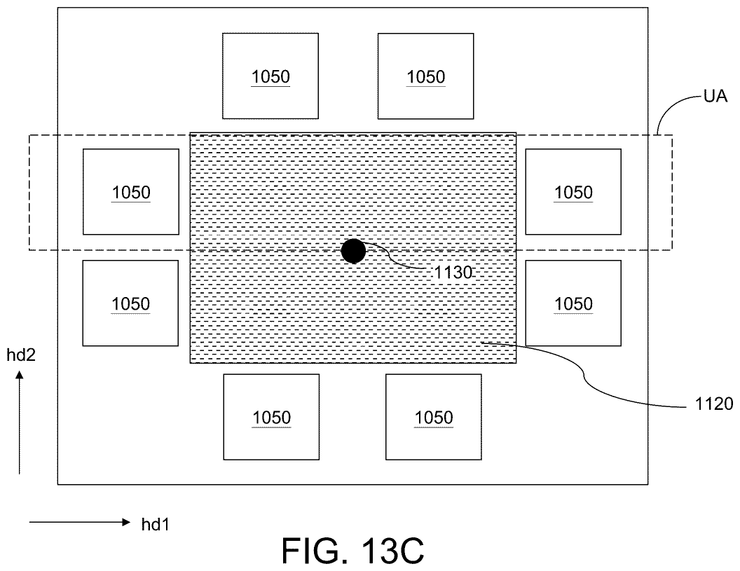

FIG. 13A shows the structure with a fastener cavity 1135 formed between components 1000 through the contact plate 1120. The fastener cavity 1135 may be formed by a drilling or etching process. The fastener cavity 1135 may have a diameter of about 5 mm to about 8 mm. Additionally, the fastener cavity 1135 may extend through the cold plate 1100, the molding compound 910M, and the interposer 920. Optionally, the fastener cavity 1135 may be smoothed by a chemical mechanical polishing or etching process.

Referring to FIGS. 13B and 13C, a fastener 1130 may be placed in the fastener cavity 1135 to apply compression force between the contact plate 1120 and the components 1000 to ensure thermal conduction between the contact plate 1120 and the components 1000. The fastener 1130 may be a bolt, screw, or other appropriate fastener. In instances where the fastener 1130 is a bolt or screw, the fastener 1130 may have a diameter of about 6 mm to about 8 mm. In some embodiments, the fastener 1130 may be loosened or tightened to adjust the contact stress between the contact plate 1120 and component 1000.

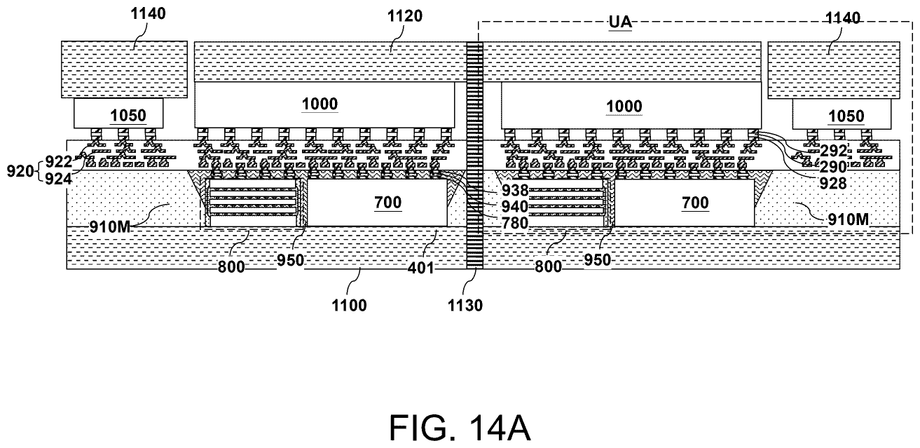

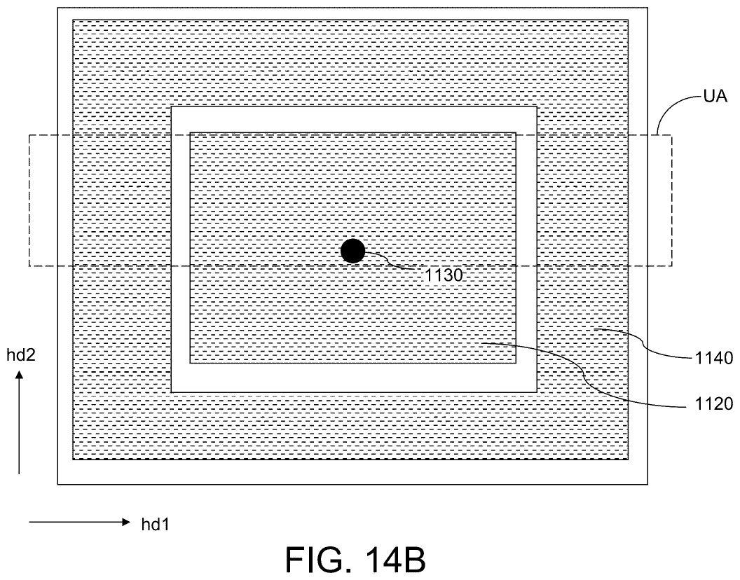

Referring to FIGS. 14A and 14B, a second contact plate 1140 may be attached to a top surface of the components 1050. In some embodiments, the second contact plate 1140 may be thermally bonded to the components 1050 using an adhesive, such as a gel TIM. In some embodiments, the contact plate 1140 has a rectangular shape with a hole in the center that surrounds the contact plate 1120. However, multiple contact plates 1140 or a contact plate 1140 with an alternative shape are within the contemplated scope of the disclosure. The contact plate 1140 may have a thickness dependent on the thickness of the components 1050 so as to provide a co-planar (or at least substantially co-planar) top surface with the first contact plate 1120 in the assembled structure. For example, component 1050 may be thinner than component 1000 resulting in contact plate 1140 being thicker than contact plate 1120 to provide co-planar top surfaces of the contact plates 1120 and 1140.

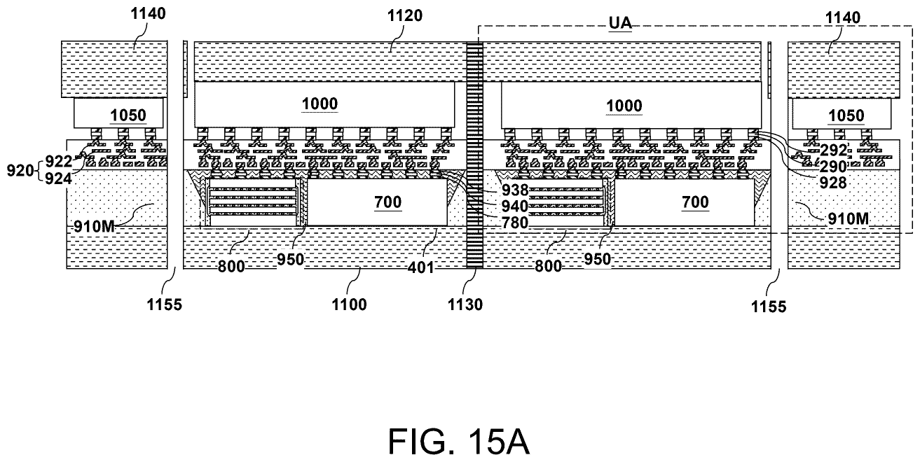

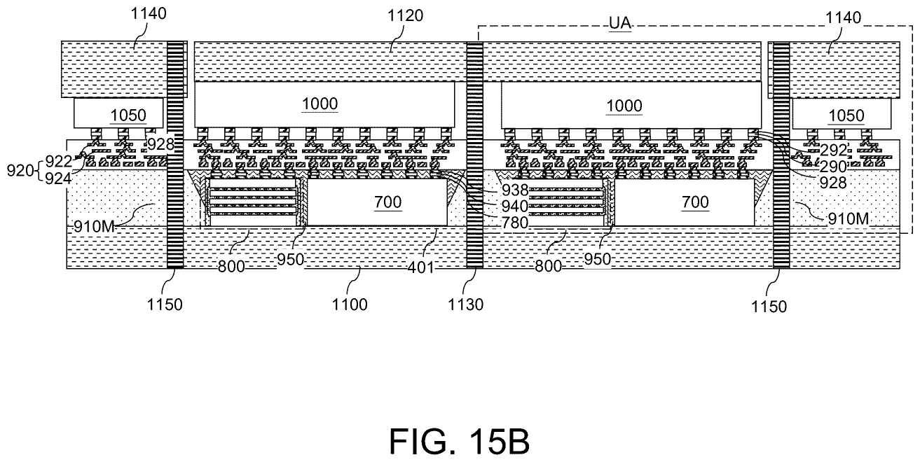

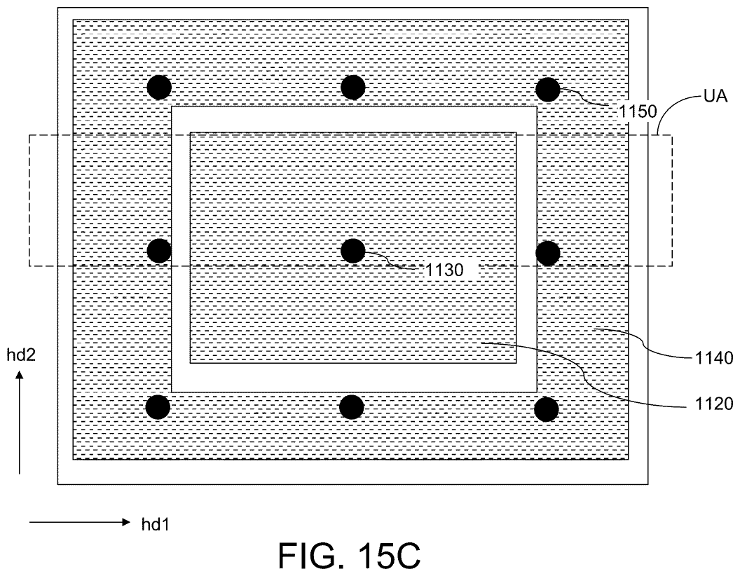

FIG. 15A shows the structure with a fastener cavity 1155 formed between components 1000 and components 1050 through the contact plate 1140. The fastener cavity 1155 may be formed by a drilling or etching process. The fastener cavity 1155 may have a diameter of about 5 mm to about 8 mm. Additionally, the fastener cavity 1155 may be located through the cold plate 1100, the molding compound 910M, and the interposer 920. Optionally, the fastener cavity 1155 may be smoothed by a chemical mechanical polishing or etching process.

Referring to FIGS. 15B and 15C, a fastener 1150 may be placed in the fastener cavity 1155 to apply compression force between the contact plate 1140 and the components 1050 to ensure efficient thermal conduction between the contact plate 1140 and components 1050. The fastener 1130 may be a bolt, screw, or other appropriate fastener. In instances where the fastener 1150 is a bolt or screw, the fastener 1150 may have a diameter of about 6 mm to about 8 mm. In some embodiments, the fastener 1150 may be loosened or tightened to adjust the contact stress between the contact plate 1140 and component 1050. In some embodiments, the contact stress between component 1000 and contact plate 1120 and component 1050 and contact plate 1140 may differ based on the type of component, heat dissipation needs, or other needs of the semiconductor package.

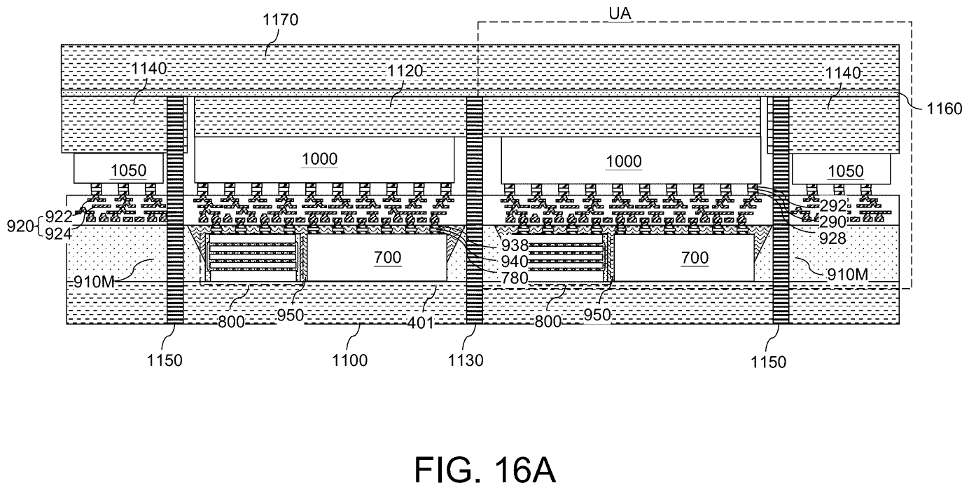

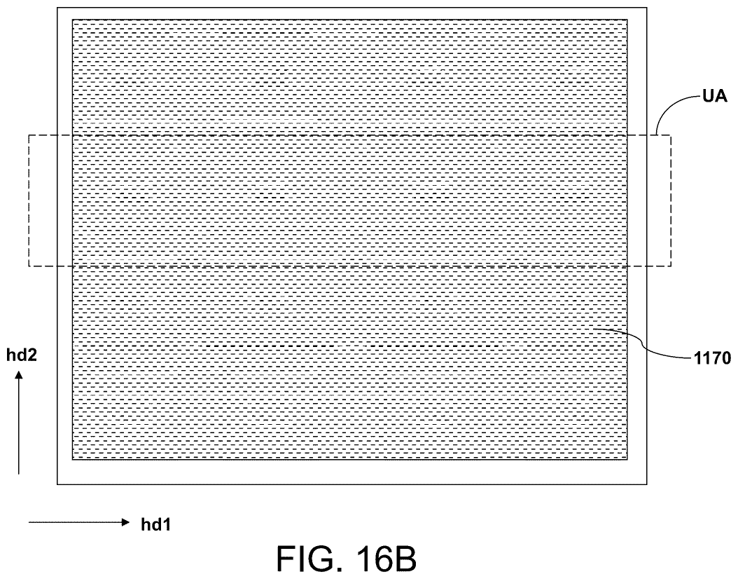

Referring to FIGS. 16A and 16B, an upper plate 1170 may optionally be attached to the top of the contact plates 1120/1140 by an adhesive 1160. In some embodiments, the upper plate 1170 may be a cold plate such as a micro-channel, brazed, press-fit, tube-in-plate, FSW, vacuum brazed, pin fin, and direct liquid cooling plates. The adhesive 1160 may be a gel TIM or other appropriate adhesive. The upper plate 1170 may provide additional heat capacity in designs in which the contact plates 1120/1140 are not adequate to dissipate heat produced by the device.

In some embodiments, holes (not shown) may be drilled within the upper plate 1170 to allow access to the fasteners 1130/1150. By allowing access to the fasteners 1130/1150 through the upper plate 1170, the fasteners 1130/1150 may be loosened or tightened aftermarket and the upper plate 1170 and/or contact plates 1120/1140 alone may be removed for service and maintenance or replaced if damage occurs.

The following discussion now refers to a number of methods and operations. Although the method operations are discussed in specific orders or are illustrated in a flow chart as being performed in a particular order, no order is required unless expressly stated or required because an operation is dependent on another operation being completed prior to the operation being performed.

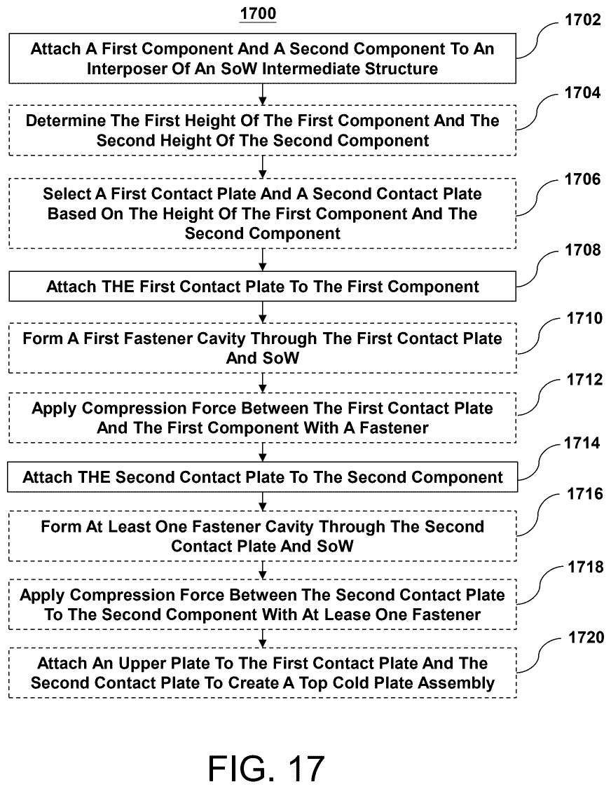

Embodiments are now described with reference to FIG. 17, which is a flow diagram of an example method 1700 for forming a semiconductor structure with a separated contact plate structure that includes a first contact plate 1120 and a second contact plate 1140. Operation 1702 may include attaching a first component 1000 and a second component 1050 to a surface of an interposer 920 in which the first component 1000 and the second component 1050 have different heights above the interposer 920 due to their different thicknesses. Referring to FIGS. 1A-1C, and 11, in operation 1702, a first component 1000 and a second component 1050 may be attached to a surface of an interposer 920. In some embodiments, the first component 1000 may be a VRM and the second component 1050 may be a connector. In some embodiments, the first component 1000 has a first thickness and the second component 1050 has a second thickness. The first thickness may differ from the second thickness (e.g., the first thickness is larger than the second thickness). In some embodiments, a third component may be provided that is attached to the surface of the interposer 920 in which the third component has a third thickness that differs from the first thickness and the second thickness.

Optional operation 1704 may include determining the first height of the first component 1000 and the second height of the second component 1050. Referring to FIGS. 1A-1C, and 11 in operation 1704, a height of the first component 1000 and a height of the second component 1050 may be determined. In some embodiments, the heights of each component 1000/1050 may be determined by measuring the heights of each component using imaging software, manual measurements, or other appropriate measurement methods. In some embodiments, the height of each component 1000/1050 may be known previously (e.g., from component design or fabrication), and the height or thickness of the component determined using an identifier (e.g., an identifier located on the component or in a data log). The first height of the first component 1000 may differ from the second height of the second component 1050. For example, the first component 1000 (e.g., a VRM) may have a height greater than the second component 1050 (e.g., a connector) due to the greater thickness of the first component.

Optional operation 1706 may include selecting the first contact plate 1120 having a first thickness based on the height (or thickness) of the first component 1000 and selecting the second contact plate 1140 having a second thickness based on the height (or thickness) of the second component 1050. Referring to FIGS. 1A-1C, 12A, and 14A in operation 1706, the first contact plate 1120 may be selected based on the height of the first component 1000 and the second contact plate 1140 may be selected based on the height of the second component 1050. In some embodiments, the first contact plate 1120 and the second contact plate 1140 may be selected from a pre-set of fabricated contact plates by software, a user, or other appropriate methods. In some embodiments, a PnP process may select the appropriate pre-fabricated contact plates 1120/1140 based on the determined height of the components 1000/1050, or the contact plates 1120/1140 may be fabricated or formed with a thickness based on the determined heights of the respective components 1000/1050.

Operation 1708 may include attaching a first contact plate 1120 to a top surface of the first component 1000. Referring to FIGS. 1A-1C, 12A, and 12B, in operation 1708, a contact plate 1120 is attached to the top surface of the first component 1000. In some embodiments, the contact plate 1120 is a cold plate (e.g., a liquid cold plate or thermoelectric cold plates). The thickness of the contact plate 1120 may be based on the thickness of the first component 1000. In some embodiments, a compression force may be applied between the first contact plate 1120 and the first component 1000 by an adhesive, fastener, or other appropriate methods.

Optional operation 1710 may include forming a first fastener cavity 1135 through the first contact plate 1120. Referring to FIG. 13A, in operation 1710, a first fastener cavity 1135 is formed through the first contact plate 1120. In some embodiments, the fastener cavity 1135 may be formed by a drilling or etching process. In some embodiments, the first fastener cavity 1135 further is located through the cold plate 1100 and molding 910M.

Optional operation 1712 may include creating thermal contact between the first contact plate 1120 and the first component 1000 by pressing the plate and component against one another with a fastener 1130 through the first fastener cavity 1135. Referring to FIGS. 1A-1C, 13B, and 13C, in optional operation 1712, compression forces are applied between the first contact plate 1120 and the first component 1000 by a fastener 1130 thereby enabling direct contact between the first component 1000 and the contact plate 1120 to ensure efficient heat conduction therebetween. In some embodiments, the fastener 1130 may be a bolt having a diameter of about 6 mm to about 8 mm. In some embodiments, the fastener may be adjustable to further adjust the stress applied on the contact plate 1120 thereby enabling proper thermal contact.

Operation 1714 may include attaching a second contact plate 1140 to a top surface of the second component 1050, in which a top surface of the second contact plate 1140 is co-planar (or at least substantially co-planar) with a top surface of the first contact plate 1130. Referring to FIGS. 1A-1C, 14A, and 14B, in operation 1714, a contact plate 1140 is attached to the top surface of the second component 1050. In some embodiments, the contact plate 1140 is a cold plate (e.g., a liquid cold plate or thermoelectric cold plates).

The thickness of the contact plate 1140 may be based on the thickness of the second component 1050 such that the top surface of the second contact plate 1140 is co-planar (or at least substantially co-planar) with the first contact plate 1120 in the assembled structure. For example, in instances in which the first component 1000 is thicker than the second component 1050, the first contact plate 1120 may be thinner than the second contact plate 1140. In some embodiments, compression forces may be applied between the second contact plate 1140 and the second component 1050 by an adhesive, fastener, or other appropriate methods to provide efficient heat conduction between the second component 1050 and the contact plate 1140.

Optional operation 1716 may include forming a second fastener cavity 1155 through the second contact plate 1140. Referring to FIG. 15A, in operation 1716, a second fastener cavity 1155 is formed through the second contact plate 1140. In some embodiments, the fastener cavity 1155 may be formed by a drilling or etching process. In some embodiments, the second fastener cavity 1155 further extends through the cold plate 1100 and molding 910M.

Optional operation 1718 may include applying compression forces between the second contact plate 1140 and the second component 1050 with a fastener 1150 through the second fastener cavity 1155. Referring to FIGS. 1A-1C, 15B, and 15C, in optional operation 1718, compression forces may be applied between the second contact plate 1140 and the second component 1050 by a fastener 1150. In some embodiments, the fastener 1150 may be a bolt with a diameter of about 6 mm to about 8 mm. In some embodiments, the fastener may be adjustable to further adjust the stress applied on the contact plate 1140. For example, fastener 1150 may be adjusted to apply more or less stress on contact plate 1140 than fastener 1130 applies on contact plate 1120.

Optional operation 1720 may include attaching an upper plate 1170 to the top surface of the first contact plate 1120 and the top surface of the second contact plate 1140. Referring to FIGS. 1A-1C, 16A, and 16B, in optional operation 1720 may attach an upper plate 1170 above the first contact plate 1120 and the second contact plate 1140. In some embodiments, the upper plate 1170 is a cold plate. The upper plate 1170 may be attached to the first contact plate 1120 and the second contact plate 1140 by an adhesive 1160. Because the top surface of the first and second contact plates are co-planar due to their different thicknesses, a flat upper plate 1170 will make a good thermal contact with the first and second contact plates in the structures.

Referring to all drawings and according to various embodiments, a semiconductor structure may include a first component 1000 having a first thickness attached to an interposer 920; a second component 1050 having a second thickness attached to the interposer 920 with a bottom surface co-planar with a bottom surface of the first component 1000, wherein the first thickness is different from the second thickness; a first contact plate 1120 with a third thickness attached to a top surface of the first component 1000; and a second contact plate 1140 with a fourth thickness attached to a top surface of the second component 1050, in which the third thickness of the first contact plate and the fourth thickness of the second contact plate are configured such that a top surface of the first contact plate 1120 is substantially co-planar with a top surface of the second contact plate 1140.

In some embodiments, the semiconductor structure further includes a first fastener 1150 configured to connect to the bottom of the SoW structure and apply compression forces between the first component 1000 and the first contact plate 1120 and a second fastener 1150 configured to connect to the bottom of the SoW structure and apply compression forces between the second component 1050 and the second contact plate 1140. In some embodiments, the first fastener 1130 and the second fastener 1150 extend through the interposer 920. In some embodiments, the first fastener 1130 and the second fastener 1150 are each a bolt having a diameter of about 6 mm to about 8 mm. In some embodiments, the semiconductor structure further includes an upper plate 1170 attached to a top surface of the first contact plate 1120 and a top surface of the second contact plate 1140. In some embodiments, the semiconductor structure further includes an adhesive 1160 applied between the upper plate 1170 and each of the first contact plate 1120 and the second contact plate 1140. In some embodiments, the semiconductor structure further includes a third component 1080 with a third thickness, in which the third thickness is different than the first thickness and the second thickness; and a third contact plate 1180 with a fifth thickness attached to a top surface of the third component 1080, in which the fifth thickness of the third contact plate 1180 is configured such that a top surface of the third contact plate 1180 is co-planar (or at least substantially co-planar) with a top surface of the second contact plate 1140 and the first contact plate 1120. In some embodiments, the semiconductor structure further includes a plurality of semiconductor dies 700/800 attached to a second surface of the interposer 920 opposite a first side attached to the first component 1000 and the second component 1050; a molding material 910M surrounding the plurality of semiconductor dies 700/800; and a cold plate 1100 attached below the molding 910M and to a bottom surface of the plurality of semiconductor dies 700/800.

In another embodiment, a separated contact plate structure may include a first contact plate 1120 configured to attach to a first component 1000; a second contact plate 1140 configured to attach to a second component 1050, in which the first contact plate 1120 has a thickness that is different than the thickness of the second contact plate 1140 based on a height of the first component 1000 and a height of the second component 1050 so that a top surface of the first contact plate 1120 is substantially co-planar with a top surface of the second contact plate 1140; and an upper plate 1170 attached to the top surface of the first contact plate 1120 and the top surface of the second contact plate 1140.

In some embodiments, the separated contact plate structure further includes a first fastener 1130 configured to connect to the bottom of the SoW structure and apply compression forces between the first component 1000 and the first contact plate 1120 and a second fastener 1150 configured to connect to the bottom of the SoW structure and apply compression forces between the second component 1050 and the second contact plate 1140. In some embodiments, the first fastener 1130 and the second fastener 1150 are each a bolt having a diameter of about 6 mm to about 8 mm. In some embodiments, the separated contact plate structure further includes an adhesive 1160 applied between the upper plate 1170 and each of the first contact plate 1120 and the second contact plate 1140. In some embodiments, the separated contact plate structure further includes a third contact plate 1180 attached to a top surface of a third component 1080, in which the third contact plate 1180 has a thickness that is different than the thickness of the first contact plate 1120 and the thickness of the second contact plate 1140 based on a height of the third component 1180 so that a top surface of the third contact plate 1180 is substantially co-planar with the top surfaces of the second contact plate 1140 and the first contact plate 1120.

In an alternative embodiment, a method for forming a semiconductor structure may include attaching a first component 1000 and a second component 1050 to a surface of an interposer 920, in which the first component 1000 and the second component 1050 have different heights above the interposer 920; attaching a first contact plate 1120 to a top surface of the first component 1000, the first contact plate 1120 has a first thickness; and attaching a second contact plate 1140 to a top surface of the second component 1050, in which the second contact plate 1120 having a second thickness different from the first thickness and the first thickness and the second thickness are such that a top surface of the second contact plate 1140 is substantially co-planar with a top surface of the first contact plate 1120.

In some embodiments, the method 1700 further includes determining the first height of the first component 1000 and the second height of the second component 1050. In some embodiments, the method further includes selecting the first contact plate 1120 having the first thickness based on the height of the first component 1000 and selecting the second contact plate 1140 having the second thickness based on the height of the second component 1050. In some embodiments, the method further includes forming a first fastener cavity 1135 through the first contact plate 1120; and forming a second fastener cavity 1155 through the second contact plate 1140. In some embodiments, the method further includes creating thermal contact between the first contact plate 1120 and the first component 1000 with a fastener 1130 through the first fastener cavity 1135; and creating thermal contact between the second contact plate 1140 and the second component 1050 with a fastener 1150 through the second fastener cavity 1155. In some embodiments, the method further includes attaching an upper plate 1170 to the top surface of the first contact plate 1120 and the top surface of the second contact plate 1140. In some embodiments, the method further includes applying an adhesive 1160 between the upper plate 1160 and the top surfaces of the first contact plate 1120 and second contact plate 1140.

Various embodiments provide multiple advantages and improvements. For example, various embodiments include separated contact plate structures that may provide effective thermal contact with components of different thicknesses or heights above the interposer, thereby enhancing overall thermal conduction and assembly cooling efficiency. Additionally, various embodiments may increase heat capacity of cold plates thereby improving thermal management. The additional cold plates may further allow for precise adjustment of contact stress to provide optimal thermal contact and thermal management performance. Various embodiments may provide uniform thermal distribution across components with varying thickness and prevent hotspots by providing consistent cooling. Further, various embodiments may maintain operating temperatures for all components regardless of their thickness thereby enhancing performance and reliability. Various embodiments may include design flexibility by allowing for adjustable contact stress through bolts or adhesives and providing flexibility to tailor cooling solutions to specific component needs. Various embodiments may also be expanded to multiple technology generations, applications, components, and cooling methods due to the flexibility, adaptability, and versatility of the separated contact plates. As a result, various embodiments may extend the operational lifespan and efficiency of a semiconductor package.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the scope of the present disclosure, and that they may make various changes, substitutions, and alterations herein without departing from the scope of the claims.

What is claimed is:

1. A semiconductor structure, comprising:
a first component having a first thickness attached to an interposer;
a second component having a second thickness attached to the interposer with a bottom surface substantially co-planar with a bottom surface of the first component, wherein the first thickness is different from the second thickness;
a first contact plate with a third thickness attached to a top surface of the first component; and
a second contact plate with a fourth thickness attached to a top surface of the second component, wherein the third thickness of the first contact plate and the fourth thickness of the second contact plate are configured such that a top surface of the first contact plate being substantially co-planar with a top surface of the second contact plate.

2. The semiconductor structure of claim 1, further comprising a first fastener configured to apply compression force between the first component and the first contact plate and a second fastener configured to apply compression force between the second component and the second contact plate.

3. The semiconductor structure of claim 2, wherein the first fastener and the second fastener extend through the interposer.

4. The semiconductor structure of claim 2, wherein the first fastener and the second fastener are each a bolt having a diameter of about 6 mm to about 8 mm.

5. The semiconductor structure of claim 1, further comprising an upper plate attached to the top surface of the first contact plate and the top surface of the second contact plate.

6. The semiconductor structure of claim 5, further comprising an adhesive applied between the upper plate and each of the first contact plate and the second contact plate.

7. The semiconductor structure of claim 1, further comprising:
a third component with a third thickness, wherein the third thickness is different than the first thickness and the second thickness; and
a third contact plate with a fifth thickness attached to a top surface of the third component, wherein the fifth thickness of the third contact plate is selected so that a top surface of the third contact plate is substantially co-planar with the top surfaces of the second contact plate and the first contact plate.

8. The semiconductor structure of claim 1, further comprising:
a plurality of semiconductor dies attached to a second surface of the interposer opposite a first side attached to the first component and the second component;
a molding material surrounding the plurality of semiconductor dies; and
a cold plate attached below the molding material and to a bottom surface of the plurality of semiconductor dies.

9. A separated contact plate structure, comprising:
a first contact plate configured to attach to a first component;
a second contact plate configured to attach to a second component, wherein the first contact plate has a thickness that is different than a thickness of the second contact plate based on a height of the first component and a height of the second component so that a top surface of the first contact plate is substantially co-planar with a top surface of the second contact plate; and
an upper plate attached to the top surface of the first contact plate and the top surface of the second contact plate.

10. The separated contact plate structure of claim 9, further comprising a first fastener configured to apply compression force between the first component and the first contact plate and a second fastener configured to apply compression force between the second component and the second contact plate.

11. The separated contact plate structure of claim 10, wherein the first fastener and the second fastener are each a bolt having a diameter of about 6 mm to about 8 mm.

12. The separated contact plate structure of claim 9, further comprising an adhesive applied between the upper plate and each of the first contact plate and the second contact plate.

13. The separated contact plate structure of claim 9, further comprising a third contact plate attached to a top surface of a third component, wherein the third contact plate has a thickness that is different than the thickness of the first contact plate and the thickness of the second contact plate based on a height of the third component so that a top surface of the third contact plate is substantially co-planar with the top surfaces of the second contact plate and the first contact plate.

14. A method for forming a semiconductor structure with a separated contact plate structure, comprising;
attaching a first component and a second component to a surface of an interposer, wherein the first component and the second component have different heights above the interposer;
attaching a first contact plate to a top surface of the first component, the first contact plate having a first thickness; and
attaching a second contact plate to a top surface of the second component, the second contact plate having a second thickness that is different from the first thickness, wherein the first thickness and the second thickness are such that a top surface of the second contact plate is substantially co-planar with a top surface of the first contact plate.

15. The method of claim 14, further comprising determining a first height of the first component and a second height of the second component.

16. The method of claim 15, further comprising:
selecting the first contact plate having the first thickness based on the first height of the first component; and
selecting the second contact plate having the second thickness based on the second height of the second component.

17. The method of claim 14, further comprising:
forming a first fastener cavity through the first contact plate; and
forming a second fastener cavity through the second contact plate.

18. The method of claim 16, further comprising:
applying compression force between the first contact plate and the first component with a first fastener through the first fastener cavity; and
applying compression force between the second contact plate and the second component with a second fastener through the second fastener cavity.

19. The method of claim 16, further comprising attaching an upper plate to the top surface of the first contact plate and the top surface of the second contact plate.

20. The method of claim 19, further comprising applying an adhesive between the upper plate and the top surfaces of the first contact plate and second contact plate.
